(19) United States
(12) Patent Application Publication
(10) Pub. No.: US 2025/0169027 A1
(43) Pub. Date: May 22, 2025

(54) METHODS AND APPARATUS TO ENHANCE COOLING OF COMPUTING DEVICES

(71) Applicant: Intel Corporation, Santa Clara, CA (US)

(72) Inventors: Shantanu Dattatraya Kulkarni, Hillsboro, OR (US); James Raupp, Hillsboro, OR (US)

(73) Assignee: Intel Corporation, Santa Clara, CA (US)

(21) Appl. No.: 19/028,679

(22) Filed: Jan. 17, 2025

(51) Int. Cl. H05K 7/20; G06F 1/20

(52) U.S. Cl. CPC H05K 7/20209; G06F 1/20; H05K 7/20172

(57) ABSTRACT

Systems, apparatus, articles of manufacture, and methods to enhance cooling of computing devices are disclosed. An example apparatus includes a blower housing, and an impeller carried by the blower housing. The impeller is to rotate to force air out through an outlet of the blower housing. The example apparatus further includes an ionic cooling system carried by the blower housing. The ionic cooling system is to force air out through the outlet of the blower housing.

### BACKGROUND

Integrated circuits (ICs) such as processor circuitry of computing devices produce heat during operation. Some such computing devices employ one or more fans to force air across the ICs and/or an associated heatsink thermally coupled to the ICs to help dissipate the generated heat. In this way, the ICs can be maintained at suitable temperature levels that avoid overheating.

### BRIEF DESCRIPTION OF THE DRAWINGS

FIG. 1 is a cross-sectional view of an example blower constructed in accordance with teachings disclosed herein.

FIG. 2 is a perspective view of the example blower of FIG. 1.

FIG. 3 is a cross-sectional view of another example blower constructed in accordance with teachings disclosed herein.

FIG. 4 is a perspective view of the example blower of FIG. 3.

FIG. 5 is a cross-sectional view of another example blower shown in spatial relationship to other components of an associated computing device.

FIG. 6 is a perspective view of the example blower of FIG. 5.

FIG. 7 is another cross-sectional view of the example blower of FIG. 5 with an example cover for an inlet moved to an open position.

FIG. 8 is a perspective view of the example blower of FIG. 7 with the example cover in the open position.

FIG. 9 is a top view of another example blower with another example cover in a closed position.

FIG. 10 is a top view of the example blower of FIG. 9 with the example cover moved to an open position.

FIG. 11 is a graph representing example flow rates relative to noise levels that can be achieved in accordance with teachings disclosed herein.

FIG. 12 is a block diagram of example blower control circuitry that may be implemented to control any of the example blowers of FIGS. 1-10.

FIG. 13 is a flowchart representative of example machine readable instructions and/or example operations that may be executed, instantiated, and/or performed by example programmable circuitry to implement the blower control circuitry of FIG. 12.

FIG. 14 is a block diagram of an example processing platform including programmable circuitry structured to execute, instantiate, and/or perform the example machine readable instructions and/or perform the example operations of FIG. 13 to implement the blower control circuitry of FIG. 12.

FIG. 15 is a block diagram of an example implementation of the programmable circuitry of FIG. 14.

FIG. 16 is a block diagram of another example implementation of the programmable circuitry of FIG. 14.

FIG. 17 is a block diagram of an example software/firmware/instructions distribution platform (e.g., one or more servers) to distribute software, instructions, and/or firmware (e.g., corresponding to the example machine readable instructions of FIG. 13) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings.

### DETAILED DESCRIPTION

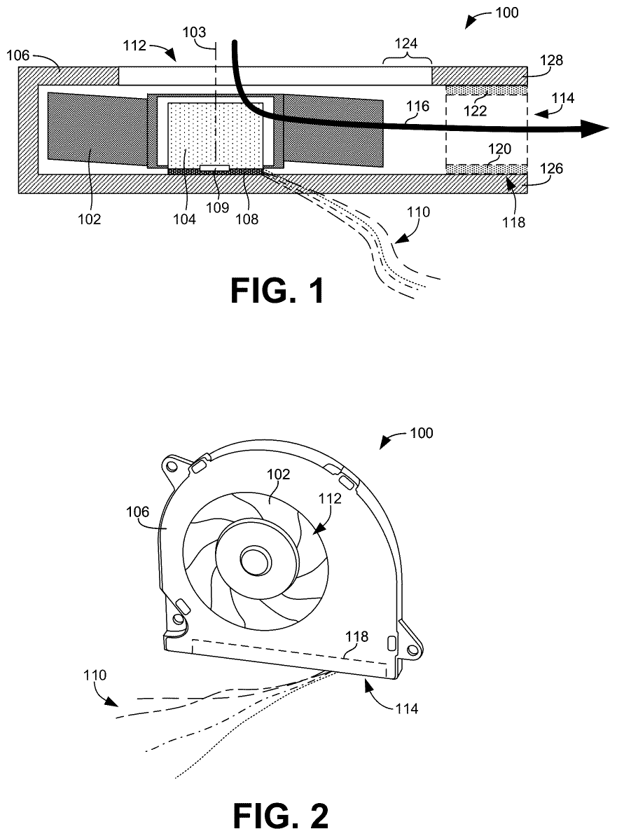

FIG. 1 is a cross-sectional view of an example cooling blower 100 (e.g., air blower, air mover, cooling assembly) constructed in accordance with teachings disclosed herein. FIG. 2 is a perspective view of the example blower 100 of FIG. 1. The example blower 100 of FIGS. 1 and 2 includes an impeller 102 (e.g., a fan) that rotates about an axis 103 as driven by a motor 104. Both the impeller 102 and the motor 104 are disposed within a housing 106 (e.g., a casing). That is, the impeller 102 and the motor 104 are positioned between opposing walls (e.g., a first outer wall 126 and a second outer wall 128) of the housing 106. In this example, the motor 104 is mounted to a control board 108 (e.g., a circuit board) containing impeller control circuitry 109 to control operation of the motor 104 and the impeller 102. In this example, the control board 108 is carried by the blower housing 106 with cables 110 extending from the blower 100 to be operatively coupled to external components within a larger system (e.g., a computing device). In some examples, some or all of the impeller control circuitry 109 and/or the associated control board 108 are external to the blower housing 106. For instance, in some examples, the control board 108 corresponds to a main board (e.g., a motherboard) of an associated computing device containing the example blower 100.

When the impeller 102 is activated (e.g., rotated by the motor 104) air is drawn in through an inlet 112 (e.g., a first opening in a wall) of the housing 106 and forced out through an outlet 114 (e.g., a second opening in the same or different wall) of the housing 106 according to the air flow path represented by the arrow 116 in FIG. 1. In some examples, the housing 106 defines a volute structure (e.g., a curved funnel shaped structure) to direct the air blown by the impeller 102 towards the outlet 114. In some examples, the speed of rotation of the impeller 102 can be adjusted to increase or decrease the flow rate of air blown by the blower 100. Generally speaking, higher air flow rates (corresponding to a faster moving impeller) provide more cooling capacity than slower air flow rates. However, faster rotation of the impeller 102 associated with higher air flow rates generally corresponds to greater noise. Such noise produced by the rotating impeller 102 can distract, annoy, and/or otherwise negatively impact the experience of a user of an associated computing device containing the blower 100. Thus, as with many known blowers, there is a tradeoff between improving heat dissipation on one hand and improving user experience on the other.

The example blower 100 of FIGS. 1 and 2 includes an ionic cooling system 118 (e.g., an ionic air mover, an ionic blowing machine, an ionic engine) to force air out through the outlet 114 independent of the impeller 102. Ionic cooling systems are solid-state devices that strip air molecules of electrons, thereby producing ions, based on a high voltage applied across two diodes (e.g., an emitter and a collector). The ionized air molecules are then attracted towards the collector. The resulting movement of the ionized air molecules causes the surrounding air molecules to also move, thereby generating ionic flow of air. Inasmuch as ionic cooling systems are solid-state devices with no moving parts, the resulting air flow is generated without any appreciable noise.

In some examples, the inlet 112 in the housing includes an area 124 that extends beyond the outer perimeter of the impeller 102 towards the ionic cooling system 118 to provide an open pathway for air to access the upstream side of the ionic cooling system 118. This area 124 of the inlet 112 helps reduce inlet impedance to the ionic cooling system 118, which has a lower stagnation pressure than the impeller 102. That is, the area 124 of the inlet 112 helps reduce the hydraulic resistance for ionic air flow, thereby mitigating against the relatively low pressure head associated with ionic air flow. In some examples, the area 124 may not extend beyond the outer perimeter of the impeller 102 but may still extend closer to the outlet 114 (and the associated ionic cooling system 118) than known fan blower inlets (which known fan blowers do not include the ionic cooling system 118).

For purposes of illustration and explanation, the example ionic cooling system 118 is shown in FIG. 1 with an example emitter 120 and an example collector 122 on opposite walls 126, 128 of the housing 106. However, there are different possible arrangements for the emitter 120 and the collector 122 and, more generally, the ionic cooling system 118. Examples disclosed herein include any suitable design for the ionic cooling system 118 that are able to be carried by the housing 106 of the blower 100 and in which the impeller 102 is able to force air through the outlet 114 regardless of whether the ionic cooling system 118 is active (e.g., operating) or not (e.g., turned off).

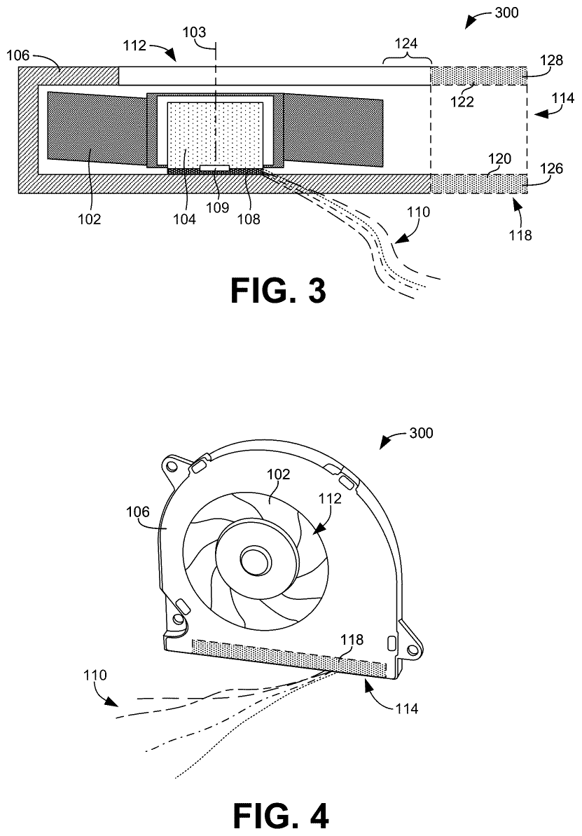

In the illustrated example of FIGS. 1 and 2, the ionic cooling system 118 is disposed within an inner volume of the housing 106. That is, the ionic cooling system 118 is between the first and second outer walls 126, 128 of the housing 106. In other examples, the ionic cooling system 118 is integrated into and/or defines part of housing 106 (e.g., part of at least one of the walls 126, 128) as shown in FIGS. 3 and 4. Specifically, FIGS. 3 and 4 illustrate another example blower 300 that is substantially the same or similar to the example blower 100 of FIGS. 1 and 2 except as noted or otherwise made clear from the context. Accordingly, the features shown in FIGS. 3 and 4 that are the same or similar to corresponding features shown in FIGS. 1 and 2 are identified by the same reference numbers and the description of such features above applies equally to the corresponding features shown in FIGS. 3 and 4. As shown in FIG. 3, the example ionic cooling system 118 corresponds to and/or defines part of the walls 126, 128 of the housing 106 of the example blower 300. Thus, as represented in FIGS. 3 and 4, at least part of the ionic cooling system 118 is exposed on an external surface of the housing 106.

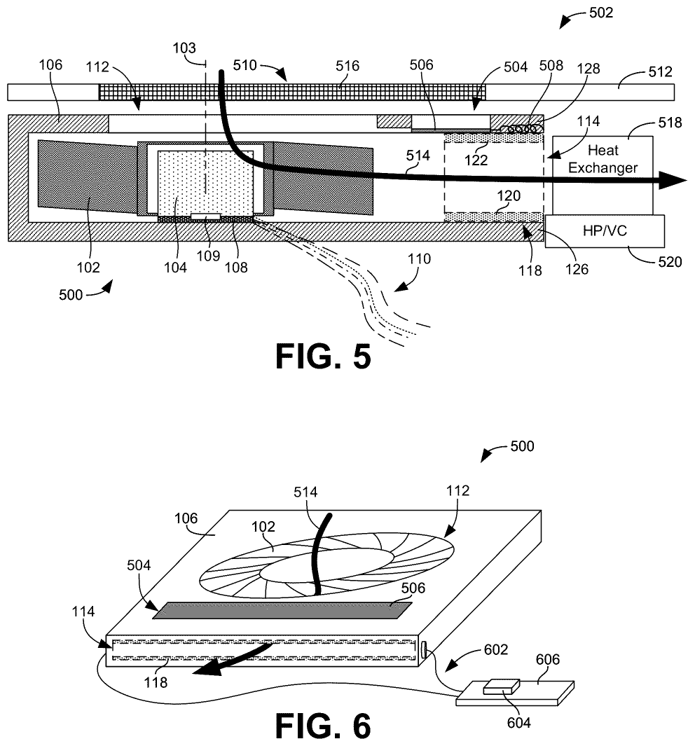

FIG. 5 is a cross-sectional view of another example blower 500 shown in spatial relationship to other components of an associated computing device 502. The computing device 502 can be any suitable computing device that employs forced air to facilitate the cooling of electronic components (e.g., ICs, processor circuitry, etc.). Thus, for example, the computing device 502 can correspond to a tablet computer, a laptop computer, a desktop computer, etc. The example blower 500 of FIG. 5 is similar to the example blowers 100, 300 of FIGS. 1 and 2 except as otherwise noted or made clear from the context. Accordingly, the features shown in FIG. 5 that are the same or similar to corresponding features shown in FIGS. 1 and 2 are identified by the same reference numbers and the description of such features above applies equally to the corresponding features shown in FIG. 5. Thus, as shown in the illustrated example, the blower 500 includes an impeller 102 and an associated motor 104 positioned adjacent an inlet 112. Further, the example blower 500 includes an ionic cooling system 118 positioned adjacent an outlet 114 of the blower 500.

In the illustrated example of FIG. 5, the inlet 112 is a first inlet (e.g., a first opening) and the housing 106 includes a second inlet 504 (e.g., a third opening) adjacent the first inlet 112. In some examples, the second inlet 504 is closer to the outlet 114 (e.g., a second opening) than the first inlet 112 is to the outlet 114. Further, in some examples, the second inlet 504 is adjacent an upstream side of the ionic cooling system 118. That is, the ionic cooling system 118 is between the second inlet 504 and the outlet 114 and the second inlet 504 is between the first inlet 112 and the ionic cooling system 118. FIG. 6 is an isometric view of the example blower 500 of FIG. 5 showing the first and second inlets 112, 504 in the housing 106.

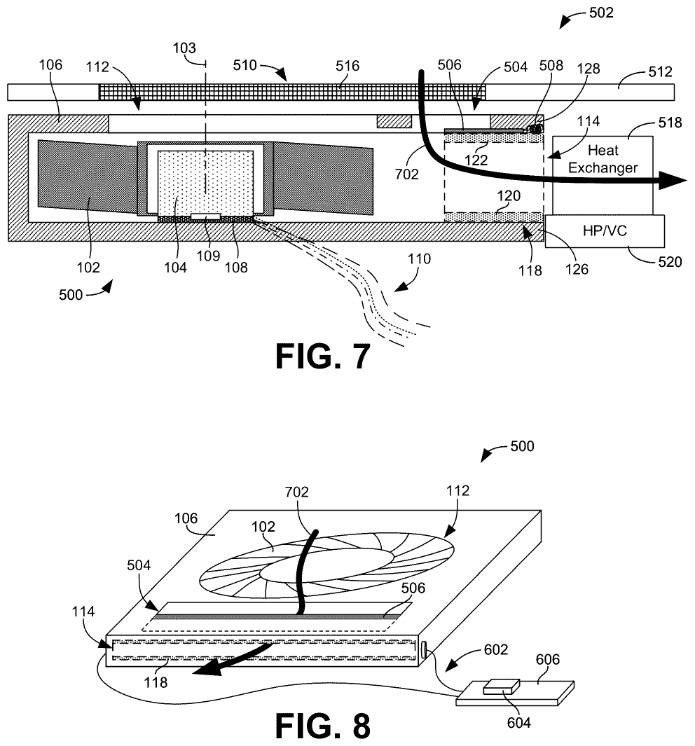

In some examples, the second inlet 504 can be selectively opened or closed by an adjustable cover 506 (e.g., a lid, a flap, etc.). FIGS. 5 and 6 show the cover 506 in a closed position in which air flow through the second inlet 504 is obstructed. In this manner, air blown by the impeller 102 can be smoothly guided to the outlet 114. By contrast, FIGS. 7 and 8 show the cover 506 in an open position to permit air to pass through the second inlet 504. Opening the second inlet 504 in this manner helps reduce inlet impedance to the blower 500 because of the lower stagnation pressure of the ionic cooling system 118 as compared to the impeller 102. That is, opening the second inlet 504 helps reduce the hydraulic resistance for ionic air flow because there is not much pressure head for ionic air flow. However, in some examples, the ionic cooling system 118 operates while the cover 506 is in the closed position. On the other hand, in some examples, the cover 506 is left in the open while the impeller 102 is operating.

In some examples, the cover 506 is moved between a closed position (FIGS. 5 and 6) and an open position (FIGS. 7 and 8) via an actuator 508. In the illustrated example, the actuator 508 includes a shape memory alloy (e.g., a shape memory alloy activated spring) that changes size in response to a change in temperature. In some such examples, an electric current is applied to the actuator 508 that causes the shape memory alloy to heat up and change size (e.g., expand or contract), thereby causing the cover 506 to move (e.g., translate) between the open and closed positions. In other examples, the actuator 508 is implemented by any other suitable type of liner actuator. For instance, in some examples, the actuator 508 includes a nut (coupled to the cover 506) that translates along a screw rotated by a motor to achieve linear movement. In some examples, the actuator 508 includes a solenoid and/or one or more springs to push and/or pull the cover 506.

Although the cover 506 is shown as a solid unitary component, in some examples, the cover 506 includes multiple sections or slats that can collapse or fold onto one another as the cover 506 is moved to the open position. Further, although the cover 506 is shown as moving towards the outlet 114 when moved to the open position, in some examples, the actuator 508 causes the cover 506 to move away from the outlet 114 (e.g., towards the first inlet 112). Further, although the cover 506 is positioned on an inside surface of the second wall 128 of the housing 106, in other examples, the cover 506 is on an outside surface of the second wall 128 of the housing 106. In other examples, the cover 506 is embedded within (e.g., positioned between the inside and outside surfaces of) the second wall 128.

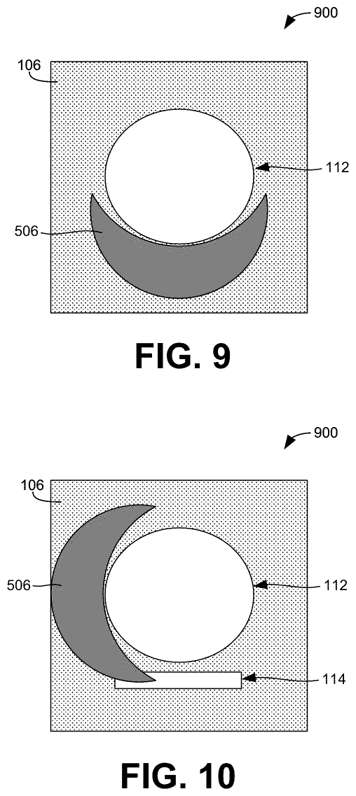

In some examples, the actuator 508 causes the cover 506 to rotate (rather than linear translate) relative to the second inlet 504 as the cover 506 moves between open and closed positions. For instance, in some examples, the actuator 508 causes the cover to rotate on a hinge. In some examples, the cover 506 is composed of multiple relatively thin slats or louvers distributed across the second inlet 504 that rotate in place to either block or permit air to pass therethrough. In some examples, the actuator 508 causes the cover 506 to rotate about an axis parallel to an axis of rotation of the impeller 102. For instance, FIG. 9 illustrates another example blower 900 with an example cover 506 in a closed position and FIG. 10 illustrates the cover 506 rotated about the first inlet 112 of the housing 106 to uncover the second inlet 504.

As shown in FIGS. 5 and 7, the example blower 500 is positioned adjacent to an opening 510 in a housing 512 of the associated computing device 502. In some examples, where the computing device 502 is a laptop computer, the portion of housing 512 shown corresponds to a C cover or a D cover of the laptop. In the illustrated example, the blower 500 is positioned so that both the first and second inlets 112, 504 of the blower housing 106 are aligned with the opening 510 in the computing device housing 512. In this manner, air from an external environment can be provided to the blower 500 following a first air flow path 514 that passes through the first inlet 112 (as shown in FIGS. 5 and 6) and/or following a second air flow path 702 that passes through the second inlet 504 (as shown in FIGS. 7 and 8). In some examples, the opening 510 is covered by a grating or mesh 516 to prevent solid objects or particles from entering the housing 512 while still permitting air to pass through. In some examples, the opening 510 is separated into two openings corresponding to the two separate inlets 112, 504. In some examples, the cover 506 is positioned on the computing device housing 512 instead of the blower housing 106.

As shown in the illustrated example, the computing device 502 includes a heat exchanger 518 adjacent to the outlet 114 of the blower 500. As a result, air blown by the impeller 102 (as represented in FIGS. 5 and 6) or by the ionic cooling system 118 (as represented in FIGS. 7 and 8) pass through the heat exchanger 518. That is, both the impeller 102 and the ionic cooling system 118 force air towards a common (e.g., a single) heat exchanger. In this example, the heat exchanger is thermally coupled to a heatsink 520 such as a heat pipe, a vapor chamber, and/or other heat conductive component. In some examples, the heatsink 520 is thermally coupled to an IC (e.g., processor circuitry) or other heat producing electronic component to draw heat away from the IC. The heat is then transferred to the heat exchanger 518 and from the heat exchanger 518 to the air passing through the heat exchanger 518 as blown by the impeller 102 and/or the ionic cooling system 118.

Integrating an impeller and an ionic cooling system into a single housing provides a number of advantages relative to known cooling techniques. As already discussed above, ionic cooling systems are solid state devices with no moving parts. As such, ionic cooling systems produce almost no sound and are substantially silent when operating. As used herein, substantially silent means the sound pressure level is less than or equal to approximately 15 A-weighted decibels (dBA). However, known ionic cooling systems produce lower air flow than is possible with known fans (e.g., a known impeller). As a result, ionic cooling systems provide less cooling capacity than fans. For instance, fan blowers can achieve air flow rates well above 2 cubic feet per minute (cfm) to dissipate as much as approximately 30 watts of thermal design power (TDP). By contrast, known ionic cooling systems can achieve air flows in excess of 1 cfm, but significantly less than 2 cfm, to dissipate up to approximately 15 watts of TDP. Fans rotating at relatively low speeds can be relatively quiet (e.g., around 20 dBA), but they still produce some level of noise and do not produce much air flow for efficient cooling at such speeds. Furthermore, to achieve the higher flow rates and more significant cooling, fans must increase speed, which results in increased noise. In some instances, noise from fans can reach up to at least 40 dBA. Thus, there is a tradeoff between greater cooling for higher performance of an associated IC when using a fan and less noise when using an ionic cooling system (or a fan at low speeds). Additionally, known ionic cooling systems consume more power than fans. Thus, there is also a tradeoff between energy efficiency (with a fan) and noise reduction (with an ionic cooling system).

One solution to obtain the best of both fans and ionic cooling systems is to implement both a fan and an ionic cooling system within the same computing device. However, known implementations of this approach involve completely independent devices at separate locations within an associated computing device. This takes up more space than examples disclosed herein where the ionic cooling system 118 is contained within the same housing 106 as the impeller 102. Moreover, in some examples, there is little to no change in the overall footprint of example blowers 100, 300, 500, 900 from a traditional fan blower because the ionic cooling system 118 can be dimensioned to fit within the volute portion of the housing 106 near the outlet 114. Furthermore, in known computing devices that include distinct and spatially separated impellers and ionic cooling systems (i.e., the ionic cooling system is external to the impeller and/or fan housing), the air blown by each device is directed towards separate heat exchangers that are thermally coupled to separate heatsinks (e.g., different heat pipes and/or different vapor chambers). As a result, such known approaches involve additional parts that take up additional space that are avoided in examples disclosed herein by arranging both the impeller 102 and the ionic cooling system 118 to blow air towards the same heat exchanger 518 and same heatsink 520.

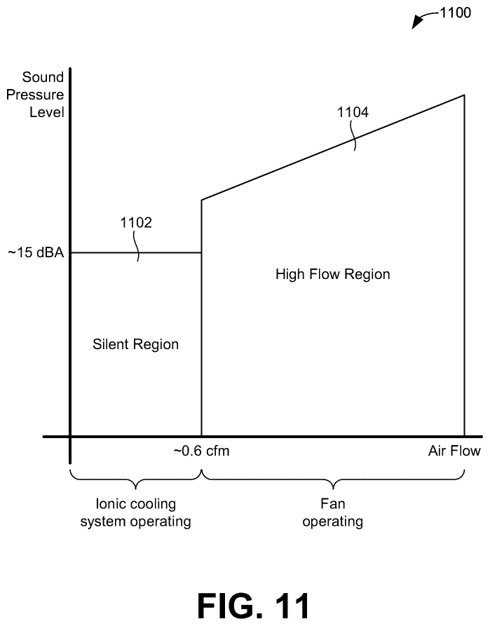

Additionally, integrating an impeller 102 and an ionic cooling system 118 into a common housing 106 enables more control of air flow towards the common heat exchanger 518 and heatsink 520 that can be tailored to the performance needs in conjunction with considerations of user experience associated with the level of noise produced by the system. More particularly, FIG. 11 is a graph 1100 representing example flow rates relative to noise levels that can be achieved in accordance with teachings disclosed herein. As shown in FIG. 11, there is a silent region 1102 associated with operation of the ionic cooling system 118 and a high flow region 1104 associated with operation of the impeller 102. The high flow region 1104 increases in noise level (e.g., sound pressure level) as the air flow increases based on an increase in the rotational speed of the impeller 102.

Although the graph 1100 of FIG. 11 shows separate regions for the ionic cooling system 118 and the impeller 102, in some examples, both the ionic cooling system 118 and the impeller 102 can be activated at the same time. In some such examples, the cover 506 is in the closed position (as shown in FIGS. 5 and 6) with pressure head for ionic air flow provided by the rotating impeller 102. In other examples, both the ionic cooling system 118 and the impeller 102 can operate simultaneously with the cover 506 in the open position (as shown in FIGS. 7 and 8).

In some examples, as shown in FIGS. 6 and 8, cables 602 connect the ionic cooling system 118 to ionic cooling circuitry 604 on an associated control board 606 (e.g., a circuit board) to control and/or power the elements of the ionic cooling system 118. In the illustrated example, the control board 606 is external to the blower 500. In some such examples, the control board 606 corresponds to a main board (e.g., motherboard) of the computing device 502. In other examples, the control board 606 is independent of a main board of the computing device 502. As discussed above, in some examples, the impeller control circuitry 109 is also implemented on the main board of the computing device 502 (instead of within the housing 106 of the blower 100 as shown in the illustrated example). In some examples, the control board 606 for the ionic cooling circuitry 604 is carried by and/or included within the housing 106 of the blower 500 (e.g., similar to the control board 108 for the impeller control circuitry 109 as shown in the illustrated example). In some examples, the control board 606 is the same as the control board 108 containing the impeller control circuitry 109 associated with the impeller 102 and the motor 104. That is, in some examples, both the impeller control circuitry 109 to control operation of the impeller 102 and the ionic cooling circuitry 604 to control operation of the ionic cooling system 118 are implemented on the same circuit board. In some such examples, this common circuit board is contained within and/or otherwise carried by the housing 106 of the blower 100. In other examples, this common circuit board is external to and independent of the blower 100 (e.g., both the impeller control circuitry 109 and the ionic cooling circuitry 604 is implemented on the main board of the computing device 502).

The foregoing examples of the blowers 100, 300, 500, 900 teach or suggest different features. Although each example blower 100, 300, 500, 900 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features. For instance, in some examples, a cover 506 (as shown in FIGS. 5-10) can be used in combination with an ionic cooling system integrated into and/or defining part of the housing 106 of the blower (as shown in FIGS. 3 and 4). Additionally or alternatively, in some examples, a blower can include two inlets (as shown in FIGS. 5-10) but omit a cover 506 to close off the inlets (as shown in FIGS. 1-4). Alternatively, in some examples, the cover 506 (as shown in FIGS. 5-10) can be implemented in connection with a housing 106 that includes only a single inlet 112 (as shown in FIGS. 1-4). More particularly, in some such examples, the cover 506 may not completely close off the inlet 112. Rather, in such examples, the cover 506 merely extends into the inlet to close off or block a portion of the inlet 112 such as the area 124 closest to the ionic cooling system 118.

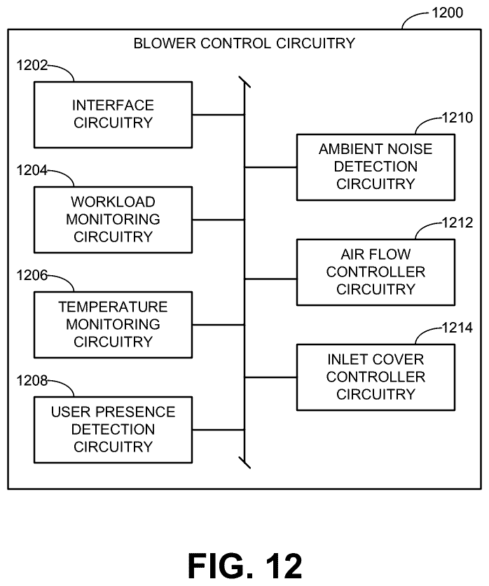

FIG. 12 is a block diagram of example blower control circuitry 1200 to control operation of any of the example blowers 100, 300, 500, 900 disclosed herein. In some examples, the blower control circuitry 1200 of FIG. 12 includes and/or implements the impeller control circuitry 109 and the ionic cooling circuitry 604 discussed above in connection with FIGS. 1-9. Thus, in some examples, some or all of the blower control circuitry 1200 is implemented on one or more control boards (e.g., the control board 108, the control board 606) carried by the housing 106 of the blower 100, 300, 500, 900. Additionally or alternatively, in some examples, some or all of the blower control circuitry 1200 is located external to the blower housing 106 (e.g., on a main board of an associated computing device containing the blower 100, 300, 500, 900). The blower control circuitry 1200 of FIG. 12 may be instantiated (e.g., creating an instance of, bring into being for any length of time, materialize, implement, etc.) by programmable circuitry such as a Central Processor Unit (CPU) executing first instructions. Additionally or alternatively, the blower control circuitry 1200 of FIG. 12 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 12 may, thus, be instantiated at the same or different times. Some or all of the circuitry of FIG. 12 may be instantiated, for example, in one or more threads executing concurrently on hardware and/or in series on hardware. Moreover, in some examples, some or all of the circuitry of FIG. 12 may be implemented by microprocessor circuitry executing instructions and/or FPGA circuitry performing operations to implement one or more virtual machines and/or containers.

As shown in FIG. 12, the example blower control circuitry 1200 includes example interface circuitry 1202, example workload monitoring circuitry 1204, example temperature monitoring circuitry 1206, example user presence detection circuitry 1208, example ambient noise detection circuitry 1210, example air flow controller circuitry 1212, and example inlet cover controller circuitry 1214.

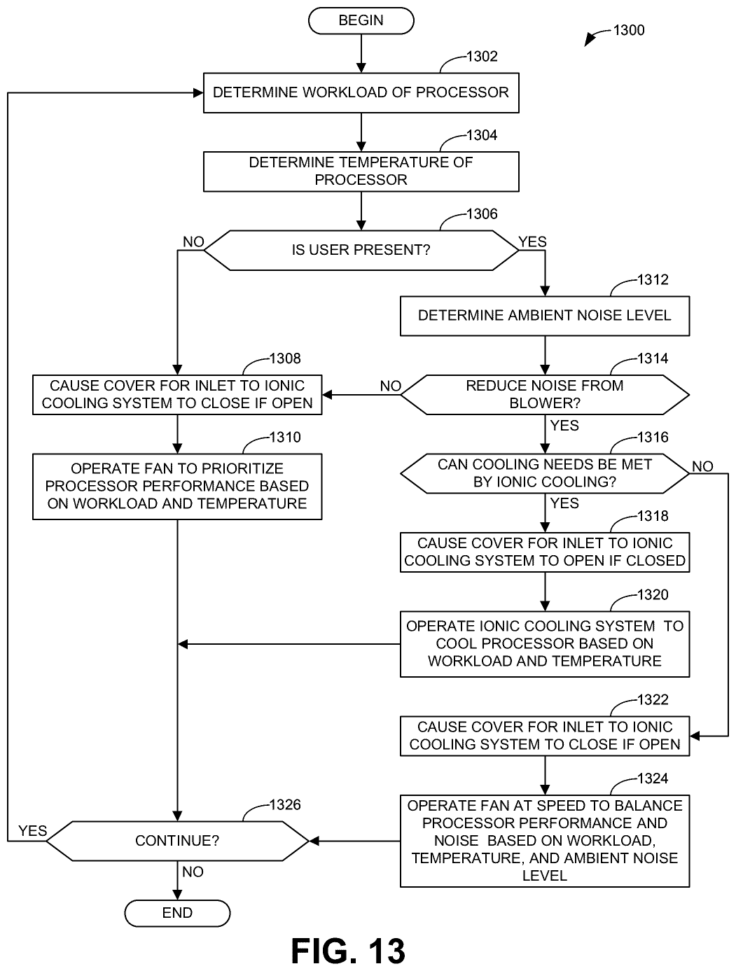

The example blower control circuitry 1200 is provided with the example interface circuitry 1202 to facilitate communications with components of the blower 100, 300, 500, 900 (e.g., the motor 104 that drives the impeller 102, the ionic cooling system 118, the actuator 508 for the cover 506, etc.). Further, in some examples, the interface circuitry 1202 enables communications with components external to the blower 100, 300, 500, 900 such as a workload scheduler for a processor of an associated computing device (e.g., the computing device 502) and/or various sensors (e.g., temperatures sensors, user detection sensors, ambient noise sensors (e.g., microphones), etc.) that can inform the blower control circuitry 1200 how to control operation of the blower 100, 300, 500, 900. In some examples, the interface circuitry 1202 is instantiated by programmable circuitry executing interface instructions and/or configured to perform operations such as those represented by the flowchart of FIG. 13.

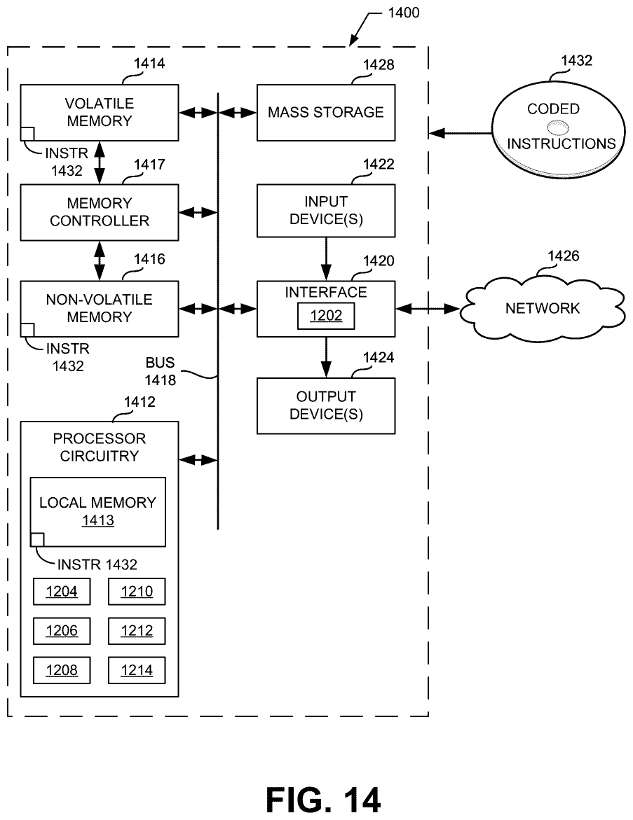

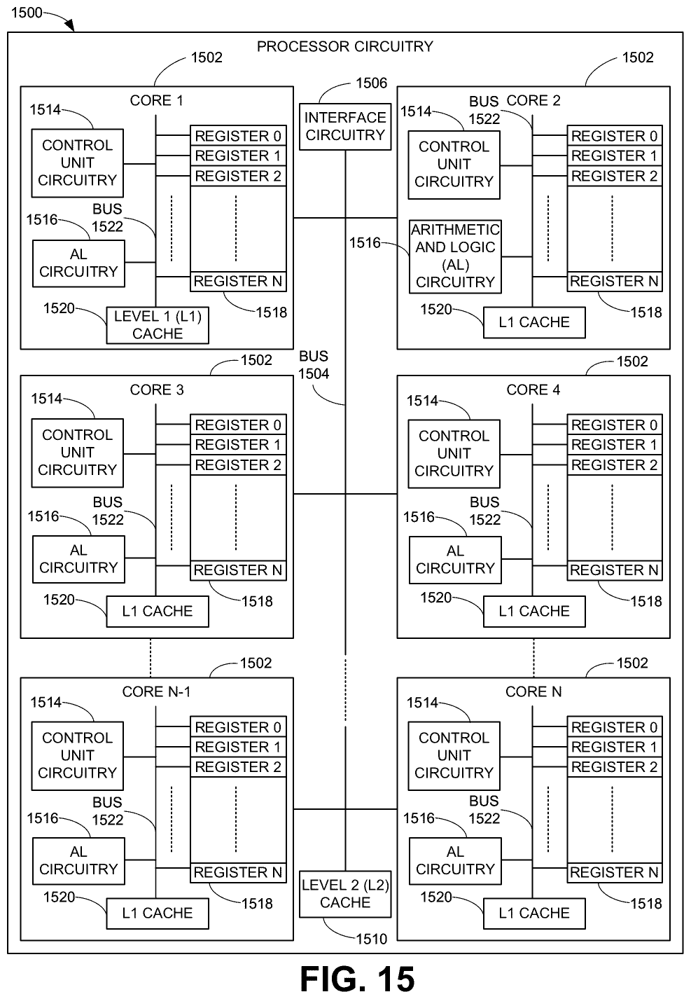

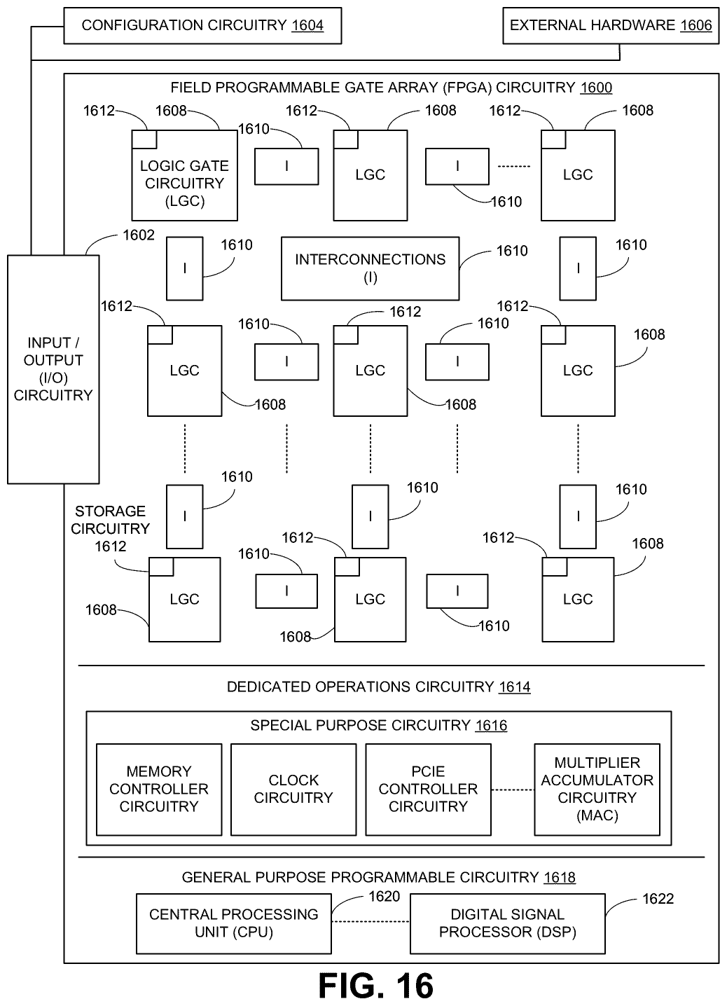

In some examples, the blower control circuitry 1200 includes means for communicating. For example, the means for communicating may be implemented by interface circuitry 1202. In some examples, the interface circuitry 1202 may be instantiated by programmable circuitry such as the example programmable circuitry 1412 of FIG. 14. For instance, the interface circuitry 1202 may be instantiated by the example microprocessor 1500 of FIG. 15 executing machine executable instructions such as those outlined in connection with FIG. 13. In some examples, the interface circuitry 1202 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the interface circuitry 1202 may be instantiated by any other combination of hardware, software, and/or firmware. For example, the interface circuitry 1202 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example blower control circuitry 1200 is provided with the example workload monitoring circuitry 1204 to monitor and/or determine a workload of a processor (e.g., a central processing unit (CPU), a graphics processing unit (GPU), etc.) to be cooled by the example blower 100, 300, 500, 900. In some examples, the workload of the processor is used as an input to determine how to control the operation of the example blower 100, 300, 500, 900 as discussed further below. In some examples, the workload monitoring circuitry 1204 determines the current (e.g., ongoing) workload of the processor. Additionally or alternatively, in some examples, the workload monitoring circuitry 1204 determines and/or predicts the workloads, tasks, and/or operations to commence in the near future. In some examples, this is based on data from a workload schedule. In some examples, the workload monitoring circuitry 1204 is instantiated by programmable circuitry executing workload monitoring instructions and/or configured to perform operations such as those represented by the flowchart of FIG. 13.

In some examples, the blower control circuitry 1200 includes means for determining a workload of a processor. For example, the means for determining may be implemented by workload monitoring circuitry 1204. In some examples, the workload monitoring circuitry 1204 may be instantiated by programmable circuitry such as the example programmable circuitry 1412 of FIG. 14. For instance, the workload monitoring circuitry 1204 may be instantiated by the example microprocessor 1500 of FIG. 15 executing machine executable instructions such as those implemented by at least block 1302 of FIG. 13. In some examples, the workload monitoring circuitry 1204 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the workload monitoring circuitry 1204 may be instantiated by any other combination of hardware, software, and/or firmware. For example, the workload monitoring circuitry 1204 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example blower control circuitry 1200 is provided with the example temperature monitoring circuitry 1206 to monitor and/or determine a temperature of a processor to be cooled by the example blower 100, 300, 500, 900. In some examples, the temperature of the processor is used as an input to determine how to control the operation of the example blower 100, 300, 500, 900 as discussed further below. In some examples, the temperature monitoring circuitry 1206 determines the temperature based on feedback from one or more temperature sensors associated with the processor. Additionally or alternatively, in some examples the temperature monitoring circuitry 1206 monitors an ambient temperature of air surrounding a computing device (e.g., the computing device 502) containing the processor to be cooled. In some examples, the ambient temperature of the surrounding environment is used as an input to determine how to control the operation of the example blower 100, 300, 500, 900. In some examples, the temperature monitoring circuitry 1206 is instantiated by programmable circuitry executing temperature monitoring instructions and/or configured to perform operations such as those represented by the flowchart of FIG. 13.

In some examples, the blower control circuitry 1200 includes means for determining a temperature of a processor. For example, the means for determining may be implemented by temperature monitoring circuitry 1206. In some examples, the temperature monitoring circuitry 1206 may be instantiated by programmable circuitry such as the example programmable circuitry 1412 of FIG. 14. For instance, the temperature monitoring circuitry 1206 may be instantiated by the example microprocessor 1500 of FIG. 15 executing machine executable instructions such as those implemented by at least block 1304 of FIG. 13. In some examples, the temperature monitoring circuitry 1206 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the temperature monitoring circuitry 1206 may be instantiated by any other combination of hardware, software, and/or firmware. For example, the temperature monitoring circuitry 1206 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example blower control circuitry 1200 is provided with the example user presence detection circuitry 1208 to determine the presence or absence of a user within the vicinity of a computing device (e.g., the computing device 502) containing the processor to be cooled by the example blower 100, 300, 500, 900. In some examples, the presence or absence of the user is used as an input to determine how to control the operation of the example blower 100, 300, 500, 900 as discussed further below. The user presence detection circuitry 1208 can determine the presence or absence of a user in any suitable way using any suitable data. For instance, in some examples, the presence or absence of a user is determined based on sound data capture by a microphone of the associated computing device, image data captured by a camera associated with the computing device, application usage data indicating applications running and/or being actively used by a user on the associated computing device, lid status data indicating the status of a lid (e.g., open or closed) in the case of the associated computing device being a laptop computer, and/or any other suitable data. In some examples, the user presence detection circuitry 1208 is instantiated by programmable circuitry executing user presence detection instructions and/or configured to perform operations such as those represented by the flowchart of FIG. 13.

In some examples, the blower control circuitry 1200 includes means for determining a presence of a user. For example, the means for determining may be implemented by user presence detection circuitry 1208. In some examples, the user presence detection circuitry 1208 may be instantiated by programmable circuitry such as the example programmable circuitry 1412 of FIG. 14. For instance, the user presence detection circuitry 1208 may be instantiated by the example microprocessor 1500 of FIG. 15 executing machine executable instructions such as those implemented by at least block 1306 of FIG. 13. In some examples, the user presence detection circuitry 1208 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the user presence detection circuitry 1208 may be instantiated by any other combination of hardware, software, and/or firmware. For example, the user presence detection circuitry 1208 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example blower control circuitry 1200 is provided with the example ambient noise detection circuitry 1210 to determine a level of ambient noise surrounding an associated computing device (e.g., the computing device 502). In some examples, the level of ambient noise is used as an input to determine how to control the operation of the example blower 100, 300, 500, 900 as discussed further below. In some examples, the ambient noise detection circuitry 1210 determines the level of ambient noise based on feedback from a microphone associated with the computing device. In some examples, the ambient noise detection circuitry 1210 is instantiated by programmable circuitry executing ambient noise detection instructions and/or configured to perform operations such as those represented by the flowchart of FIG. 13.

In some examples, the blower control circuitry 1200 includes means for determining a level of noise. For example, the means for determining may be implemented by ambient noise detection circuitry 1210. In some examples, the ambient noise detection circuitry 1210 may be instantiated by programmable circuitry such as the example programmable circuitry 1412 of FIG. 14. For instance, the ambient noise detection circuitry 1210 may be instantiated by the example microprocessor 1500 of FIG. 15 executing machine executable instructions such as those implemented by at least block 1312 of FIG. 13. In some examples, the ambient noise detection circuitry 1210 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the ambient noise detection circuitry 1210 may be instantiated by any other combination of hardware, software, and/or firmware. For example, the ambient noise detection circuitry 1210 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example blower control circuitry 1200 is provided with the example air flow controller circuitry 1212 to control operation of the components of the blower 100, 300, 500, 900 that produce air flow. That is, in some examples, the air flow controller circuitry 1212 controls the motor 104 that drives the impeller 102 and controls the voltage applied to the diodes (e.g., the emitter 120 and the collector 122) of the ionic cooling system 118. More particularly, in some examples, the air flow controller circuitry 1212 determines when the impeller 102 is to be activated and/or the speed at which the impeller is to be rotated to control the amount of resulting air flow based on a determination of an amount of power (e.g., heat) to be dissipated from a processor to be cooled. Similarly, in some examples, the air flow controller circuitry 1212 determines when the ionic cooling system 118 is to be activated and/or the voltage that is to be applied to control the amount of resulting air flow based on the amount of power (e.g., heat) to be dissipated from a processor to be cooled. In some examples, the air flow controller circuitry 1212 determines whether to activate the impeller 102 and/or the ionic cooling system 118 based on In some examples, the air flow controller circuitry 1212 controls the operation of the impeller 102 and/or the ionic cooling system 118 using pulse width modulation (PWM). In some examples, only one of the impeller 102 and the ionic cooling system 118 is active or operating at a given time. In other examples, both the impeller 102 and the ionic cooling system 118 can be activated at the same time.

In some examples, the air flow controller circuitry 1212 determines when the impeller 102 and/or the ionic cooling system 118 is to be activated based on a workload of an associated processor to be cooled (as determined by the workload monitoring circuitry 1204), a temperature of the processor (as determined by the temperature monitoring circuitry 1206), a presence or absence of a user (as determined by the user presence detection circuitry 1208), and/or an ambient noise level (as determined by the ambient noise detection circuitry 1210). More particularly, for larger and/or computationally intensive workloads, the processor is expected to consume more power and, thus, produce more heat. Accordingly, the air flow controller circuitry 1212 may determine to increase the air flow blown by the blower 100, 300, 500, 900. Similarly, an increase in the temperature of the processor is an indication of a need for more air flow to cool down the processor.

As discussed above, for relatively high air flows, the air flow controller circuitry 1212 may activate the impeller 102 because it can move more air than may be possible for the ionic cooling system 118. However, in some examples, the air flow controller circuitry 1212 balances faster speeds of the impeller 102 (for increased cooling) against negative impacts on user experience due to increased noise produced by increased impeller speed. That said, user experience is only an issue when the user is present. If no user is present, there is no concern that a high-speed impeller produces more noise. Accordingly, the example air flow controller circuitry 1212 may adjust operation of the impeller 102 between prioritizing processor performance regardless of noise (when no user is detected as present) and balancing priorities between processor performance and noise reduction when a user is present as indicated by the user presence data obtained from the user presence detection circuitry 1208.

In some situations, noise from the impeller 102 may not be a significant concern even when a user is present. For example, if the user is in an environment that is already fairly noisy, it is less likely that noise from the impeller 102 is going to bother the user as compared to a situation in which the user is in a quiet room. Accordingly, in some examples, the air flow controller circuitry 1212 adjusts the speed of the impeller 102 and/or adjust between activating the impeller 102 and/or the ionic cooling system 118 depending on the level of ambient noise as determined by the ambient noise detection circuitry 1210. In some examples, the air flow controller circuitry 1212 is instantiated by programmable circuitry executing air flow controller instructions and/or configured to perform operations such as those represented by the flowchart of FIG. 13.

In some examples, the blower control circuitry 1200 includes means for controlling operation of a blower including operation of an impeller and operation of an ionic cooling system. For example, the means for controlling may be implemented by air flow controller circuitry 1212. In some examples, the air flow controller circuitry 1212 may be instantiated by programmable circuitry such as the example programmable circuitry 1412 of FIG. 14. For instance, the air flow controller circuitry 1212 may be instantiated by the example microprocessor 1500 of FIG. 15 executing machine executable instructions such as those implemented by at least blocks 1310, 1314, 1316, 1320, 1324 of FIG. 13. In some examples, the air flow controller circuitry 1212 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the air flow controller circuitry 1212 may be instantiated by any other combination of hardware, software, and/or firmware. For example, the air flow controller circuitry 1212 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example blower control circuitry 1200 is provided with the example inlet cover controller circuitry 1214 to control operations of the actuator 508 that causes the example cover 506 of the second inlet 504 to move between open and closed positions. In some examples, the inlet cover controller circuitry 1214 monitors a position of the cover 506 and/or controls the cover 506 to specific positions at different points along a range from a fully open position to a fully closed position. In some examples, the inlet cover controller circuitry 1214 determines whether to open or close the cover 506 based on whether the impeller 102 or the ionic cooling system 118 is activated (as determined by the air flow controller circuitry 1212). More particularly, in some examples, when the ionic cooling system 118 is operating, the inlet cover controller circuitry 1214 opens the cover 506. By contrast, when the impeller 102 is operating, the inlet cover controller circuitry 1214 closes the cover 506. However, in some examples, the inlet cover controller circuitry 1214 can open the cover 506 while the impeller 102 is operating. In some such examples, the inlet cover controller circuitry 1214 opens the cover because the ionic cooling system 118 is operating simultaneously with the impeller 102. In other examples, the cover 506 can be opened when the impeller 102 is the only activated component of the blower 100, 300, 500, 900. In some examples, the inlet cover controller circuitry 1214 can close the cover 506 even when the ionic cooling system 118 is activated (regardless of whether or not the impeller 102 is also activated). In some examples, the inlet cover controller circuitry 1214 is omitted in scenarios when there is no cover 506 (as in the case of the example blowers 100, 300 of FIGS. 1-4). In some examples, the inlet cover controller circuitry 1214 is instantiated by programmable circuitry executing inlet cover controller instructions and/or configured to perform operations such as those represented by the flowchart of FIG. 13.

In some examples, the blower control circuitry 1200 includes means for adjusting a cover for an inlet of a blower. For example, the means for adjusting may be implemented by inlet cover controller circuitry 1214. In some examples, the inlet cover controller circuitry 1214 may be instantiated by programmable circuitry such as the example programmable circuitry 1412 of FIG. 14. For instance, the inlet cover controller circuitry 1214 may be instantiated by the example microprocessor 1500 of FIG. 15 executing machine executable instructions such as those implemented by at least blocks 1308, 1318, 1322 of FIG. 13. In some examples, the inlet cover controller circuitry 1214 may be instantiated by hardware logic circuitry, which may be implemented by an ASIC, XPU, or the FPGA circuitry 1600 of FIG. 16 configured and/or structured to perform operations corresponding to the machine readable instructions. Additionally or alternatively, the inlet cover controller circuitry 1214 may be instantiated by any other combination of hardware, software, and/or firmware. For example, the inlet cover controller circuitry 1214 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the blower control circuitry 1200 is illustrated in FIG. 12, one or more of the elements, processes, and/or devices illustrated in FIG. 12 may be combined, divided, re-arranged, omitted, eliminated, and/or implemented in any other way. Further, the example interface circuitry 1202, the example workload monitoring circuitry 1204, the example temperature monitoring circuitry 1206, the example user presence detection circuitry 1208, the example ambient noise detection circuitry 1210, the example air flow controller circuitry 1212, the example inlet cover controller circuitry 1214, and/or, more generally, the example blower control circuitry 1200 of FIG. 12, may be implemented by hardware alone or by hardware in combination with software and/or firmware. Thus, for example, any of the example interface circuitry 1202, the example workload monitoring circuitry 1204, the example temperature monitoring circuitry 1206, the example user presence detection circuitry 1208, the example ambient noise detection circuitry 1210, the example air flow controller circuitry 1212, the example inlet cover controller circuitry 1214, and/or, more generally, the example blower control circuitry 1200, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example blower control circuitry 1200 of FIG. 12 may include one or more elements, processes, and/or devices in addition to, or instead of, those illustrated in FIG. 12, and/or may include more than one of any or all of the illustrated elements, processes and devices.

A flowchart representative of example machine readable instructions, which may be executed by programmable circuitry to implement and/or instantiate the blower control circuitry 1200 of FIG. 12 and/or representative of example operations which may be performed by programmable circuitry to implement and/or instantiate the blower control circuitry 1200 of FIG. 12, is shown in FIG. 13. The machine readable instructions may be one or more executable programs or portion(s) of one or more executable programs for execution by programmable circuitry such as the programmable circuitry 1412 shown in the example processor platform 1400 discussed below in connection with FIG. 14 and/or may be one or more function(s) or portion(s) of functions to be performed by the example programmable circuitry (e.g., an FPGA) discussed below in connection with FIGS. 15 and/or 16. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart illustrated in FIG. 13, many other methods of implementing the example blower control circuitry 1200 may alternatively be used. For example, the order of execution of the blocks of the flowchart may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIG. 13 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 13 is a flowchart representative of example machine readable instructions and/or example operations 1300 that may be executed, instantiated, and/or performed by programmable circuitry to control operation of any one of the example blowers 100, 300, 500, 900 disclosed herein that include both an impeller 102 and an ionic cooling system 118. The example machine-readable instructions and/or the example operations 1300 of FIG. 13 begin at block 302, at which the example workload monitoring circuitry 1204 determines a workload of a processor. At block 1304, the example temperature monitoring circuitry 1206 determines a temperature of the processor. At block 1306, the example user presence detection circuitry 1208 determines whether a user is present. If no user is detected as present, control advances to block 1308.

At block 1308, the example inlet cover controller circuitry 1214 causes (e.g., via the actuator 508) a cover (e.g., the cover 506) for an inlet (e.g., the second inlet 504) to the ionic cooling system 118 to close if open. In some examples, block 1308 is omitted or skipped if, for example, the associated blower does not include a cover (as in the example blowers 100, 300 of FIGS. 1-4) or the cover is to remain open even when the impeller 102 is to be activated. Thereafter, at block 1310, the example air flow controller circuitry 1212 is to operate a fan (e.g., the impeller 102) to prioritize processor performance based on the workload and temperature. Notably, processor performance can be prioritized in this scenario because it has already been determined (at block 1306) that no user is present such that added noise negatively impacting user experience is not a concern. Thereafter, control advances to block 1326.

Returning to block 1306, if the example user presence detection circuitry 1208 determines that a user is present, control advances to block 1312 where the example ambient noise detection circuitry 1210 determines an ambient noise level. At block 1314, the example air flow controller circuitry 1212 determines whether to reduce noise from the blower. In some examples, this is at least partially based on the ambient noise level (determined at block 1312). If the ambient noise level is relatively high (e.g., above a noise threshold), such that the noise produced by the impeller 102 operating at high speeds is to have little impact on user experience, then the example air flow controller circuitry 1212 determines there is no need to reduce noise. Accordingly, control advances to block 1308 to proceed as discussed above. On the other hand, if the example air flow controller circuitry 1212 determines that noise is to be reduced, control advances to block 1316.

At block 1316, the example air flow controller circuitry 1212 determines whether cooling needs can be met by ionic cooling. If so, control advances to block 1318 where the example inlet cover controller circuitry 1214 causes (e.g., via the actuator 508) the cover 506 for the second inlet 504 to the ionic cooling system 118 to open if closed. In some examples, block 1318 is omitted or skipped if, for example, the associated blower does not include a cover (as in the example blowers 100, 300 of FIGS. 1-4) or the cover is to remain closed while the ionic cooling system 118 is active. Thereafter, at block 1320, the example air flow controller circuitry 1212 is to operate the ionic cooling system 118 to cool the processor based on the workload and temperature. Notably, as a solid-state device, operation of the ionic cooling system 118 is substantially silent such that there is no concern about noise negatively impacting user experience. Thereafter, control advances to block 1326.

Returning to block 1316, if the example air flow controller circuitry 1212 determines that the cooling needs cannot be met by ionic cooling control advances to block 1322. At block 1322, the example inlet cover controller circuitry 1214 causes (e.g., via the actuator 508) the cover 506 for the second inlet 504 to the ionic cooling system 118 to close if opened. In some examples, block 1322 is omitted or skipped if, for example, the associated blower does not include a cover (as in the example blowers 100, 300 of FIGS. 1-4) or the cover 506 is to remain open even though the impeller 102 is to be activated. In some such examples, the cover 506 may remain open because the ionic cooling system is to remain active. At block 1324, the example air flow controller circuitry 1212 is to operate the fan (e.g., the impeller 102) to balance processor performance and noise based on the workload, temperature, and ambient noise level. Thereafter, control advances to block 1326. At block 1326, the example blower control circuitry 1200 determined whether to continue the process. If so, control returns to block 1302. Otherwise, the example program of FIG. 13 ends.

FIG. 14 is a block diagram of an example programmable circuitry platform 1400 structured to execute and/or instantiate the example machine-readable instructions and/or the example operations of FIG. 13 to implement the blower control circuitry 1200 of FIG. 12. The programmable circuitry platform 1400 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1400 of the illustrated example includes programmable circuitry 1412. The programmable circuitry 1412 of the illustrated example is hardware. For example, the programmable circuitry 1412 can be implemented by one or more integrated circuits, logic circuits, FPGAs, microprocessors, CPUs, GPUs, DSPs, and/or microcontrollers from any desired family or manufacturer. The programmable circuitry 1412 may be implemented by one or more semiconductor based (e.g., silicon based) devices. In this example, the programmable circuitry 1412 implements the example workload monitoring circuitry 1204, the example temperature monitoring circuitry 1206, the example user presence detection circuitry 1208, the example ambient noise detection circuitry 1210, the example air flow controller circuitry 1212, and the example inlet cover controller circuitry 1214.

The programmable circuitry 1412 of the illustrated example includes a local memory 1413 (e.g., a cache, registers, etc.). The programmable circuitry 1412 of the illustrated example is in communication with main memory 1414, 1416, which includes a volatile memory 1414 and a non-volatile memory 1416, by a bus 1418. The volatile memory 1414 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1416 may be implemented by flash memory and/or any other desired type of memory device. Access to the main memory 1414, 1416 of the illustrated example is controlled by a memory controller 1417. In some examples, the memory controller 1417 may be implemented by one or more integrated circuits, logic circuits, microcontrollers from any desired family or manufacturer, or any other type of circuitry to manage the flow of data going to and from the main memory 1414, 1416.

The programmable circuitry platform 1400 of the illustrated example also includes interface circuitry 1420. The interface circuitry 1420 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1422 are connected to the interface circuitry 1420. The input device(s) 1422 permit(s) a user (e.g., a human user, a machine user, etc.) to enter data and/or commands into the programmable circuitry 1412. The input device(s) 1422 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1424 are also connected to the interface circuitry 1420 of the illustrated example. The output device(s) 1424 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1420 of the illustrated example, thus, typically includes a graphics driver card, a graphics driver chip, and/or graphics processor circuitry such as a GPU.

The interface circuitry 1420 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1426. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1400 of the illustrated example also includes one or more mass storage discs or devices 1428 to store firmware, software, and/or data. Examples of such mass storage discs or devices 1428 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1432, which may be implemented by the machine readable instructions of FIG. 13, may be stored in the mass storage device 1428, in the volatile memory 1414, in the non-volatile memory 1416, and/or on at least one non-transitory computer readable storage medium such as a CD or DVD which may be removable.

FIG. 15 is a block diagram of an example implementation of the programmable circuitry 1412 of FIG. 14. In this example, the programmable circuitry 1412 of FIG. 14 is implemented by a microprocessor 1500. For example, the microprocessor 1500 may be a general-purpose microprocessor (e.g., general-purpose microprocessor circuitry). The microprocessor 1500 executes some or all of the machine-readable instructions of the flowchart of FIG. 13 to effectively instantiate the circuitry of FIG. 12 as logic circuits to perform operations corresponding to those machine readable instructions. In some such examples, the circuitry of FIG. 12 is instantiated by the hardware circuits of the microprocessor 1500 in combination with the machine-readable instructions. For example, the microprocessor 1500 may be implemented by multi-core hardware circuitry such as a CPU, a DSP, a GPU, an XPU, etc. Although it may include any number of example cores 1502 (e.g., 1 core), the microprocessor 1500 of this example is a multi-core semiconductor device including N cores. The cores 1502 of the microprocessor 1500 may operate independently or may cooperate to execute machine readable instructions. For example, machine code corresponding to a firmware program, an embedded software program, or a software program may be executed by one of the cores 1502 or may be executed by multiple ones of the cores 1502 at the same or different times. In some examples, the machine code corresponding to the firmware program, the embedded software program, or the software program is split into threads and executed in parallel by two or more of the cores 1502. The software program may correspond to a portion or all of the machine readable instructions and/or operations represented by the flowchart of FIG. 13.

The cores 1502 may communicate by a first example bus 1504. In some examples, the first bus 1504 may be implemented by a communication bus to effectuate communication associated with one(s) of the cores 1502. For example, the first bus 1504 may be implemented by at least one of an Inter-Integrated Circuit (I2C) bus, a Serial Peripheral Interface (SPI) bus, a PCI bus, or a PCIe bus. Additionally or alternatively, the first bus 1504 may be implemented by any other type of computing or electrical bus. The cores 1502 may obtain data, instructions, and/or signals from one or more external devices by example interface circuitry 1506. The cores 1502 may output data, instructions, and/or signals to the one or more external devices by the interface circuitry 1506. Although the cores 1502 of this example include example local memory 1520 (e.g., Level 1 (L1) cache that may be split into an L1 data cache and an L1 instruction cache), the microprocessor 1500 also includes example shared memory 1510 that may be shared by the cores (e.g., Level 2 (L2 cache)) for high-speed access to data and/or instructions. Data and/or instructions may be transferred (e.g., shared) by writing to and/or reading from the shared memory 1510. The local memory 1520 of each of the cores 1502 and the shared memory 1510 may be part of a hierarchy of storage devices including multiple levels of cache memory and the main memory (e.g., the main memory 1414, 1416 of FIG. 14). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1502 may be referred to as a CPU, DSP, GPU, etc., or any other type of hardware circuitry. Each core 1502 includes control unit circuitry 1514, arithmetic and logic (AL) circuitry (sometimes referred to as an ALU) 1516, a plurality of registers 1518, the local memory 1520, and a second example bus 1522. Other structures may be present. For example, each core 1502 may include vector unit circuitry, single instruction multiple data (SIMD) unit circuitry, load/store unit (LSU) circuitry, branch/jump unit circuitry, floating-point unit (FPU) circuitry, etc. The control unit circuitry 1514 includes semiconductor-based circuits structured to control (e.g., coordinate) data movement within the corresponding core 1502. The AL circuitry 1516 includes semiconductor-based circuits structured to perform one or more mathematic and/or logic operations on the data within the corresponding core 1502. The AL circuitry 1516 of some examples performs integer based operations. In other examples, the AL circuitry 1516 also performs floating-point operations. In yet other examples, the AL circuitry 1516 may include first AL circuitry that performs integer-based operations and second AL circuitry that performs floating-point operations. In some examples, the AL circuitry 1516 may be referred to as an Arithmetic Logic Unit (ALU).

The registers 1518 are semiconductor-based structures to store data and/or instructions such as results of one or more of the operations performed by the AL circuitry 1516 of the corresponding core 1502. For example, the registers 1518 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1518 may be arranged in a bank as shown in FIG. 15. Alternatively, the registers 1518 may be organized in any other arrangement, format, or structure, such as by being distributed throughout the core 1502 to shorten access time. The second bus 1522 may be implemented by at least one of an I2C bus, a SPI bus, a PCI bus, or a PCIe bus.

Each core 1502 and/or, more generally, the microprocessor 1500 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1500 is a semiconductor device fabricated to include many transistors interconnected to implement the structures described above in one or more integrated circuits (ICs) contained in one or more packages.

The microprocessor 1500 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1500, in the same chip package as the microprocessor 1500 and/or in one or more separate packages from the microprocessor 1500.

FIG. 16 is a block diagram of another example implementation of the programmable circuitry 1412 of FIG. 14. In this example, the programmable circuitry 1412 is implemented by FPGA circuitry 1600. For example, the FPGA circuitry 1600 may be implemented by an FPGA. The FPGA circuitry 1600 can be used, for example, to perform operations that could otherwise be performed by the example microprocessor 1500 of FIG. 15 executing corresponding machine readable instructions. However, once configured, the FPGA circuitry 1600 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1500 of FIG. 15 described above (which is a general purpose device that may be programmed to execute some or all of the machine readable instructions represented by the flowchart of FIG. 13 but whose interconnections and logic circuitry are fixed once fabricated), the FPGA circuitry 1600 of the example of FIG. 16 includes interconnections and logic circuitry that may be configured, structured, programmed, and/or interconnected in different ways after fabrication to instantiate, for example, some or all of the operations/functions corresponding to the machine readable instructions represented by the flowchart of FIG. 13. In particular, the FPGA circuitry 1600 may be thought of as an array of logic gates, interconnections, and switches. The switches can be programmed to change how the logic gates are interconnected by the interconnections, effectively forming one or more dedicated logic circuits (unless and until the FPGA circuitry 1600 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 13. As such, the FPGA circuitry 1600 may be configured and/or structured to effectively instantiate some or all of the operations/functions corresponding to the machine readable instructions of the flowchart of FIG. 13 as dedicated logic circuits to perform the operations/functions corresponding to those software instructions in a dedicated manner analogous to an ASIC. Therefore, the FPGA circuitry 1600 may perform the operations/functions corresponding to the some or all of the machine readable instructions of FIG. 13 faster than the general-purpose microprocessor can execute the same.

In the example of FIG. 16, the FPGA circuitry 1600 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1600 of FIG. 16 may access and/or load the binary file to cause the FPGA circuitry 1600 of FIG. 16 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1600 of FIG. 16 to cause configuration and/or structuring of the FPGA circuitry 1600 of FIG. 16, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1600 of FIG. 16 may access and/or load the binary file to cause the FPGA circuitry 1600 of FIG. 16 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1600 of FIG. 16 to cause configuration and/or structuring of the FPGA circuitry 1600 of FIG. 16, or portion(s) thereof.

The FPGA circuitry 1600 of FIG. 16, includes example input/output (I/O) circuitry 1602 to obtain and/or output data to/from example configuration circuitry 1604 and/or external hardware 1606. For example, the configuration circuitry 1604 may be implemented by interface circuitry that may obtain a binary file, which may be implemented by a bit stream, data, and/or machine-readable instructions, to configure the FPGA circuitry 1600, or portion(s) thereof. In some such examples, the configuration circuitry 1604 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1606 may be implemented by external hardware circuitry. For example, the external hardware 1606 may be implemented by the microprocessor 1500 of FIG. 15.

The FPGA circuitry 1600 also includes an array of example logic gate circuitry 1608, a plurality of example configurable interconnections 1610, and example storage circuitry 1612. The logic gate circuitry 1608 and the configurable interconnections 1610 are configurable to instantiate one or more operations/functions that may correspond to at least some of the machine readable instructions of FIG. 13 and/or other desired operations. The logic gate circuitry 1608 shown in FIG. 16 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1608 to enable configuration of the electrical structures and/or the logic gates to form circuits to perform desired operations/functions. The logic gate circuitry 1608 may include other electrical structures such as look-up tables (LUTs), registers (e.g., flip-flops or latches), multiplexers, etc.

The configurable interconnections 1610 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1608 to program desired logic circuits.

The storage circuitry 1612 of the illustrated example is structured to store result(s) of the one or more of the operations performed by corresponding logic gates. The storage circuitry 1612 may be implemented by registers or the like. In the illustrated example, the storage circuitry 1612 is distributed amongst the logic gate circuitry 1608 to facilitate access and increase execution speed.

The example FPGA circuitry 1600 of FIG. 16 also includes example dedicated operations circuitry 1614. In this example, the dedicated operations circuitry 1614 includes special purpose circuitry 1616 that may be invoked to implement commonly used functions to avoid the need to program those functions in the field. Examples of such special purpose circuitry 1616 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1600 may also include example general purpose programmable circuitry 1618 such as an example CPU 1620 and/or an example DSP 1622. Other general purpose programmable circuitry 1618 may additionally or alternatively be present such as a GPU, an XPU, etc., that can be programmed to perform other operations.

Although FIGS. 15 and 16 illustrate two example implementations of the programmable circuitry 1412 of FIG. 14, many other approaches are contemplated. For example, FPGA circuitry may include an on-board CPU, such as one or more of the example CPU 1620 of FIG. 15. Therefore, the programmable circuitry 1412 of FIG. 14 may additionally be implemented by combining at least the example microprocessor 1500 of FIG. 15 and the example FPGA circuitry 1600 of FIG. 16. In some such hybrid examples, one or more cores 1502 of FIG. 15 may execute a first portion of the machine readable instructions represented by the flowchart of FIG. 13 to perform first operation(s)/function(s), the FPGA circuitry 1600 of FIG. 16 may be configured and/or structured to perform second operation(s)/function(s) corresponding to a second portion of the machine readable instructions represented by the flowchart of FIG. 13, and/or an ASIC may be configured and/or structured to perform third operation(s)/function(s) corresponding to a third portion of the machine readable instructions represented by the flowchart of FIG. 13.

It should be understood that some or all of the circuitry of FIG. 12 may, thus, be instantiated at the same or different times. For example, same and/or different portion(s) of the microprocessor 1500 of FIG. 15 may be programmed to execute portion(s) of machine-readable instructions at the same and/or different times. In some examples, same and/or different portion(s) of the FPGA circuitry 1600 of FIG. 16 may be configured and/or structured to perform operations/functions corresponding to portion(s) of machine-readable instructions at the same and/or different times.

In some examples, some or all of the circuitry of FIG. 12 may be instantiated, for example, in one or more threads executing concurrently and/or in series. For example, the microprocessor 1500 of FIG. 15 may execute machine readable instructions in one or more threads executing concurrently and/or in series. In some examples, the FPGA circuitry 1600 of FIG. 16 may be configured and/or structured to carry out operations/functions concurrently and/or in series. Moreover, in some examples, some or all of the circuitry of FIG. 12 may be implemented within one or more virtual machines and/or containers executing on the microprocessor 1500 of FIG. 15.

In some examples, the programmable circuitry 1412 of FIG. 14 may be in one or more packages. For example, the microprocessor 1500 of FIG. 15 and/or the FPGA circuitry 1600 of FIG. 16 may be in one or more packages. In some examples, an XPU may be implemented by the programmable circuitry 1412 of FIG. 14, which may be in one or more packages. For example, the XPU may include a CPU (e.g., the microprocessor 1500 of FIG. 15, the CPU 1620 of FIG. 16, etc.) in one package, a DSP (e.g., the DSP 1622 of FIG. 16) in another package, a GPU in yet another package, and an FPGA (e.g., the FPGA circuitry 1600 of FIG. 16) in still yet another package.

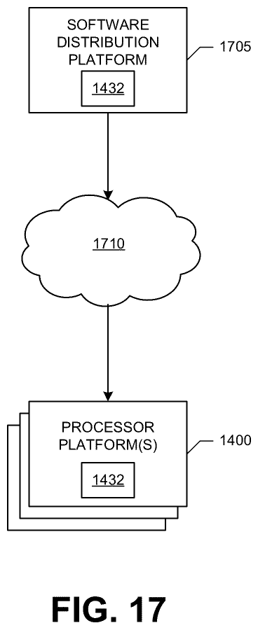

A block diagram illustrating an example software distribution platform 1705 to distribute software such as the example machine readable instructions 1432 of FIG. 14 to other hardware devices (e.g., hardware devices owned and/or operated by third parties from the owner and/or operator of the software distribution platform) is illustrated in FIG. 17. The example software distribution platform 1705 may be implemented by any computer server, data facility, cloud service, etc., capable of storing and transmitting software to other computing devices. The third parties may be customers of the entity owning and/or operating the software distribution platform 1705. For example, the entity that owns and/or operates the software distribution platform 1705 may be a developer, a seller, and/or a licensor of software such as the example machine readable instructions 1432 of FIG. 14. The third parties may be consumers, users, retailers, OEMs, etc., who purchase and/or license the software for use and/or re-sale and/or sub-licensing. In the illustrated example, the software distribution platform 1705 includes one or more servers and one or more storage devices. The storage devices store the machine readable instructions 1432, which may correspond to the example machine readable instructions of FIG. 13, as described above. The one or more servers of the example software distribution platform 1705 are in communication with an example network 1710, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1432 from the software distribution platform 1705. For example, the software, which may correspond to the example machine readable instructions of FIG. 13, may be downloaded to the example programmable circuitry platform 1400, which is to execute the machine readable instructions 1432 to implement the blower control circuitry 1200. In some examples, one or more servers of the software distribution platform 1705 periodically offer, transmit, and/or force updates to the software (e.g., the example machine readable instructions 1432 of FIG. 14) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that combine an impeller and an ionic cooling system into a single housing for an improved blower that blows air to cool an IC across a wider range of sound pressure levels (including at levels that are substantially silent) than known blowers. Furthermore, examples blowers disclosed herein have substantially the same footprint as known blowers thereby saving space relative to other systems that implement separate impeller and ionic flow based blowers. Moreover, integrating both an impeller and an ionic cooling system into a single housing enables both air moving components to blow air towards a single (common) heat exchanger rather than separate heat exchangers, thereby reducing parts and saving more space than other known cooling systems. Disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes an apparatus comprising a blower housing, an impeller carried by the blower housing, the impeller to rotate to force air out through an outlet of the blower housing, and an ionic cooling system carried by the blower housing, the ionic cooling system to force air out through the outlet of the blower housing.

Example 2 includes the apparatus of example 1, wherein the ionic cooling system is closer to the outlet than the impeller.

Example 3 includes the apparatus of any of examples 1 or 2, wherein the blower housing includes a first wall on a first side and a second wall on a second side opposite the first side, the impeller to rotate about an axis extending between the first side and the second side.

Example 4 includes the apparatus of example 3, wherein the ionic cooling system is between the first and second walls of the blower housing.

Example 5 includes the apparatus of example 3, wherein the ionic cooling system is integrated into at least one of the first wall or the second wall.

Example 6 includes the apparatus of any of examples 1-5, including ionic cooling circuitry to control operation of the ionic cooling system, the ionic cooling circuitry on a circuit board external to the blower housing.

Example 7 includes the apparatus of any of examples 1-5, including ionic cooling circuitry to control operation of the ionic cooling system, the ionic cooling circuitry on a circuit board carried by the blower housing.

Example 8 includes the apparatus of example 7, wherein the circuit board includes impeller control circuitry to control operation of a motor that drives the impeller.

Example 9 includes the apparatus of any of examples 1-8, wherein the blower housing includes a first inlet to provide air flow to the impeller, and a second inlet to provide air flow to the ionic cooling system.

Example 10 includes the apparatus of example 9, wherein the second inlet is disposed between the impeller and the ionic cooling system.

Example 11 includes the apparatus of any of examples 9 or 10, further including a cover to selectively block and unblock the second inlet.

Example 12 includes the apparatus of example 11, further including an actuator to move the cover between a closed position and an open position, the cover to block the second inlet when the cover is in the closed position, the cover to unblock the second inlet when the cover is in the open position.

Example 13 includes the apparatus of example 12, wherein the impeller is to force air through the outlet when the cover is in the closed position and the ionic cooling system is to force air through the outlet when the cover is in the open position.

Example 14 includes the apparatus of any of examples 1-13, wherein the blower housing includes an inlet to provide air flow to the impeller, the inlet including an area that extends beyond an outer perimeter of the impeller in a direction towards the ionic cooling system.

Example 15 includes the apparatus of example 14, including a flap to move between a first position to cover the area of the inlet and a second position spaced away from the area of the inlet.

Example 16 includes an apparatus comprising a blower including a fan, and an ionic air mover, and a heat exchanger towards which both the fan and the ionic cooling system are to force air.

Example 17 includes the apparatus of example 16, wherein the blower includes a flap to selectively cover or uncover at least a portion of an inlet to the ionic air mover.

Example 18 includes an apparatus including interface circuitry, machine readable instructions, at least one processor circuit to execute the instructions to determine an amount of power to be dissipated from an integrated circuit (IC), and activate at least one of a fan or an ionic cooling system based on the amount of power, the fan and the ionic cooling system being within a blower assembly housing.

Example 19 includes the apparatus of example 18, wherein one or more of the at least one processor circuit is to cause a flap to open to uncover an opening in the blower assembly housing when the ionic cooling system is activated, and cause the flap to close to cover the opening when the ionic cooling system is not activated.

Example 20 includes the apparatus of any of examples 18 or 19, wherein one or more of the at least one processor circuit is to cause a switch between activation and deactivation of at least one of the fan or the ionic cooling system based on at least one of a workload of the IC, a temperature of the IC, a presence of a user, or an ambient noise level.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a blower housing;
an impeller carried by the blower housing, the impeller to rotate to force air out through an outlet of the blower housing; and
an ionic cooling system carried by the blower housing, the ionic cooling system to force air out through the outlet of the blower housing.

2. The apparatus of claim 1, wherein the ionic cooling system is closer to the outlet than the impeller.

3. The apparatus of claim 1, wherein the blower housing includes a first wall on a first side and a second wall on a second side opposite the first side, the impeller to rotate about an axis extending between the first side and the second side.

4. The apparatus of claim 3, wherein the ionic cooling system is between the first and second walls of the blower housing.

5. The apparatus of claim 3, wherein the ionic cooling system is integrated into at least one of the first wall or the second wall.

6. The apparatus of claim 1, including ionic cooling circuitry to control operation of the ionic cooling system, the ionic cooling circuitry on a circuit board external to the blower housing.

7. The apparatus of claim 1, including ionic cooling circuitry to control operation of the ionic cooling system, the ionic cooling circuitry on a circuit board carried by the blower housing.

8. The apparatus of claim 7, wherein the circuit board includes impeller control circuitry to control operation of a motor that drives the impeller.

9. The apparatus of claim 1, wherein the blower housing includes:
a first inlet to provide air flow to the impeller; and
a second inlet to provide air flow to the ionic cooling system.

10. The apparatus of claim 9, wherein the second inlet is disposed between the impeller and the ionic cooling system.

11. The apparatus of claim 9, further including a cover to selectively block and unblock the second inlet.

12. The apparatus of claim 11, further including an actuator to move the cover between a closed position and an open position, the cover to block the second inlet when the cover is in the closed position, the cover to unblock the second inlet when the cover is in the open position.

13. The apparatus of claim 12, wherein the impeller is to force air through the outlet when the cover is in the closed position and the ionic cooling system is to force air through the outlet when the cover is in the open position.

14. The apparatus of claim 1, wherein the blower housing includes an inlet to provide air flow to the impeller, the inlet including an area that extends beyond an outer perimeter of the impeller in a direction towards the ionic cooling system.

15. The apparatus of claim 14, including a flap to move between a first position to cover the area of the inlet and a second position spaced away from the area of the inlet.

16. An apparatus comprising:
a blower including:
a fan; and
an ionic air mover; and
a heat exchanger towards which both the fan and the ionic cooling system are to force air.

17. The apparatus of claim 16, wherein the blower includes a flap to selectively cover or uncover at least a portion of an inlet to the ionic air mover.

18. An apparatus including:
interface circuitry;
machine readable instructions;
at least one processor circuit to execute the instructions to:
determine an amount of power to be dissipated from an integrated circuit (IC); and
activate at least one of a fan or an ionic cooling system based on the amount of power, the fan and the ionic cooling system being within a blower assembly housing.

19. The apparatus of claim 18, wherein one or more of the at least one processor circuit is to:
cause a flap to open to uncover an opening in the blower assembly housing when the ionic cooling system is activated; and
cause the flap to close to cover the opening when the ionic cooling system is not activated.

20. The apparatus of claim 18, wherein one or more of the at least one processor circuit is to cause a switch between activation and deactivation of at least one of the fan or the ionic cooling system based on at least one of a workload of the IC, a temperature of the IC, a presence of a user, or an ambient noise level.
